(19) United States
(12) Patent Application Publication
(10) Pub. No.: US 2010/0275999 A1
(43) Pub. Date: Nov. 4, 2010

(54) Photovoltaic Conversion Assembly with Concentrating Optics

(75) Inventor: Roger F. Buelow II, Gates Mills, OH (US)

Correspondence Address: BRUZGA & ASSOCIATES, 11 BROADWAY, SUITE 715, NEW YORK, NY, 10004, US

(73) Assignee: Energy Focus, Inc., Solon, OH (US)

(21) Appl. No.: 12/773,611

(22) Filed: May 4, 2010

Related U.S. Application Data
(60) Provisional application No. 61/175,414, filed on May 4, 2009.
(60) Provisional application No. 61/179,787, filed on May 20, 2009.

(51) Int. Cl. H01L 31/00

(52) U.S. Cl. 136/259

(57) ABSTRACT

A photovoltaic conversion assembly comprises an optical slab with first and second major surfaces and an intermediate surface therebetween. Light energy to be collected impinges as incoming photons on the first major surface. At least one PV cell is mounted to receive light energy from the intermediate surface of the optical slab and convert such light energy to electrical energy. The PV cell has a highest band gap E. A down-converting structure is located on the second major surface of the slab for converting to lower energy light received through the slab, with at least about 75 percent of the converted light having an energy level above the band gap E. A two-way spectrally selective reflector, located proximate the first major surface, cooperates with the down-converting structure for preventing high angle light from undesirably exiting the optical slab via the first major surface.

### FIELD OF THE INVENTION

The present invention relates to a photovoltaic conversion assembly with integrated concentrating optics.

### BACKGROUND OF THE INVENTION

In an effort to increase the efficiency of conversion of solar or other light energy to electricity, photovoltaic conversion assemblies with integrated concentrating optics have been proposed. One such prior art photovoltaic conversion assembly includes an optical slab formed into a rectangular solid, and serving as concentrating optics to provide concentrated light to one or more PV cells. A “first major surface”—as used herein—of the slab receives solar or other light energy and a second major surface is provided with a phosphor layer for absorbing photons that pass through the slab and for re-emitting photons at a lower energy. The one or more PV cells are mounted to edges of the slab formed between the first and second major surfaces.

A drawback of the foregoing photovoltaic conversion assembly is that the re-emitted light is often at an angle too high for transmission within the slab to the PV cells at the endges. Such light simply passes out of the slab through the first major surface and is wasted.

Another prior art photovoltaic conversion assembly is similar to the first-mentioned prior art assembly, but instead of having a phosphor layer on its second major surface, its optical slab incorporates throughout some concentration of a dye or other light-scattering means having the property of absorbing photons at one energy level and re-emitting photons at a lower energy level. A drawback, similar to that mentioned above for the first-mentioned prior art assembly, is that re-emitted light often escapes from the optical slab via its first major surface. A further drawback is that re-emitted light is susceptible being re-absorbed or scattered by the dye, etc. interspersed in the optical slab, further reducing the light reaching the PV cells. Such light is wasted.

It would, therefore, be desirable to provide a photovoltaic voltage assembly including an optical slab with a first major surface for receiving solar or other light energy and a second major surface having a means for absorbing photons and re-emitting photons at a lower energy, wherein the following benefit occurs. The assembly desirably includes means for minimizing loss of re-emitted light from the optical slab through the first major surface, so as to increase transmission of light through the optical slab to the PV cells.

### BRIEF SUMMARY OF THE INVENTION

In a preferred form, the invention provides a photovoltaic conversion assembly comprising an optical slab with first and second major surfaces and an intermediate surface therebetween. Light energy to be collected impinges as incoming photons on the first major surface. At least one PV cell is mounted to receive light energy from the intermediate surface of the optical slab and convert such light energy to electrical energy. The PV cell has a highest band gap E. A down-converting structure is located on the second major surface of the slab for converting to lower energy light received through the slab, with at least about 75 percent of the converted light having an energy level above the band gap E. A two-way spectrally selective reflector is located proximate the first major surface for reflecting away from the slab incoming photons in a reflected energy range and transmitting into the slab higher energy incoming photons in an adjacent transmitted energy range. The reflected energy range extends from a cut-off point between the reflected and transmitted energy ranges and includes the energy of the band gap E.

Beneficially, the two-way spectrally selective reflector cooperates with the down-converting structure to retain high angle light in the optical slab from the down-converting structure. This increases the light transmitted within the optical slab to the PV cells.

### BRIEF DESCRIPTION OF THE DRAWINGS

Other advantages and features of the invention will become apparent from reading the following description in connection with the following drawings, in which like reference numbers refer to like parts:

FIG. 1 is a cross section of a prior art photovoltaic conversion assembly.

FIG. 2 is a cross section of another prior art photovoltaic conversion assembly.

FIG. 3 is a cross section of a photovoltaic conversion assembly and associated graphs in accordance with the invention.

FIG. 4A is a top plan view of photovoltaic conversion assembly 30 of FIG. 3

FIG. 4B is similar to FIG. 4A, but shows an alternative top plan view of photovoltaic conversion assembly 30 of FIG. 3

FIG. 4C is a cross section of photovoltaic conversion assembly 30 of FIG. 4 taken at arrows 4C, 4C in FIG. 4B.

FIG. 5A is a cross section of photovoltaic conversion assembly 30 taken at arrows 5A, 5A in FIG. 4A.

FIGS. 5B and 5C are similar to FIG. 5A, and show alternative embodiments of photovoltaic conversion assemblies in accordance with the invention.

FIG. 5D is a top plan view of photovoltaic conversion assembly 74 of FIG. 5B.

FIG. 5E is an enlarged detail view of photovoltaic conversion assembly 74 of FIG. 5B taken in the area bounded by the circle marked FIG. 5E.

FIG. 6 is a cross section generally similar to FIG. 5B, but shows a further embodiment in which an additional PV cell is used.

FIGS. 7A and 7B are cross sections of three adjacent photovoltaic conversion assemblies and a common mirror.

FIG. 7B is a cross section of a photovoltaic conversion assembly and an integrated mirror.

FIG. 8A is a top view of a preferred photovoltaic conversion assembly.

FIG. 8B is a cross section taken at arrows 8B-8B in FIG. 8A.

### DETAILED DESCRIPTION OF THE PREFERRED EMBODIMENT

Various embodiments of the inventive photovoltaic conversion assemblies are described, with the most preferred embodiment described last. In this specification, like-named parts have the same structure or property. This description covers the three sections of (1) Prior Art and Inventive Embodiment, (2) Definitions of Claim Terms, and (3) Other Embodiments.

### (1) Prior Art and Inventive Embodiment

To place the invention in perspective, two prior art photovoltaic conversion assemblies are described before describing an inventive embodiment.

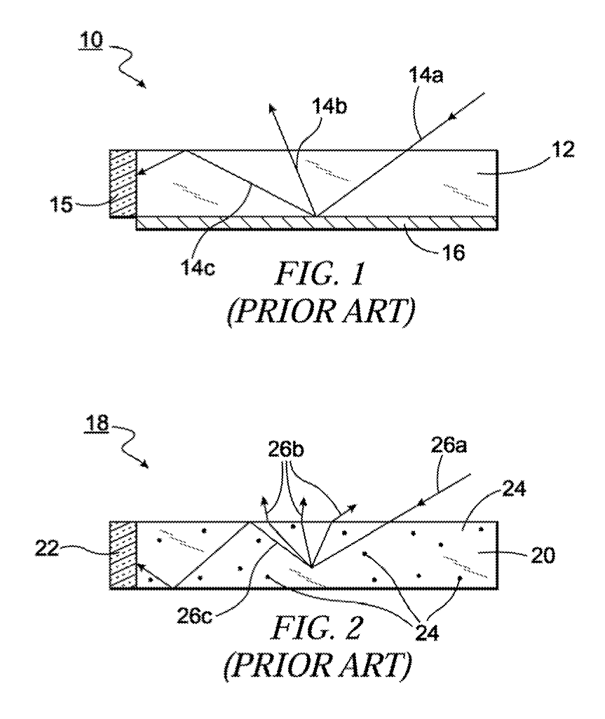

FIG. 1 shows a prior art photovoltaic conversion assembly 10. Assembly 10 includes an optical slab 12 for receiving incoming light, such as 14a, with the goal of transmitting the light to a photovoltaic (PV) cell 15. Incoming light 14a passes through optical slab 12 and is received by a down-converting means 16, such as a phosphor-containing layer. Down-converting means 16 absorbs light at one energy level, and re-emits light, such as light 14b or 14c at a lower energy level. Typically, light 14b or 14c from a down-converting means will be emitted at any upward angle in FIG. 1, but only certain angles of emitted light are shown for sake of explanation.

Down-converted light 14b reaches the upper major surface of the optical slab 12 at such a high angle that it passes out of the slab and thus thwarts the goal of reaching PV cell 15. However, down-converted light 14c does reach PV cell 15. Since a significant number of rays of down-converted light, such as 14b, which never reach PV cell 15, the overall efficiency of light to electrical power conversion suffers.

FIG. 2 shows another photovoltaic conversion assembly 18 with an optical slab 20 and PV cell 22. A down-converting means 24 comprises a dye or other light-scattering means having the property of absorbing incoming light, such as 26a, at one energy level, and re-emitting light such as 26b and 26c at a lower energy level. Transmitted light 26b reaches the upper surface of optical slab 20 at a high angle and escapes from the slab. However, transmitted light 26c does reach the PV cell 22 and contributes to energy conversion. Since, a significant amount of transmitted light 26b never reaches the PV cell 22, the efficiency of assembly 18 suffers.

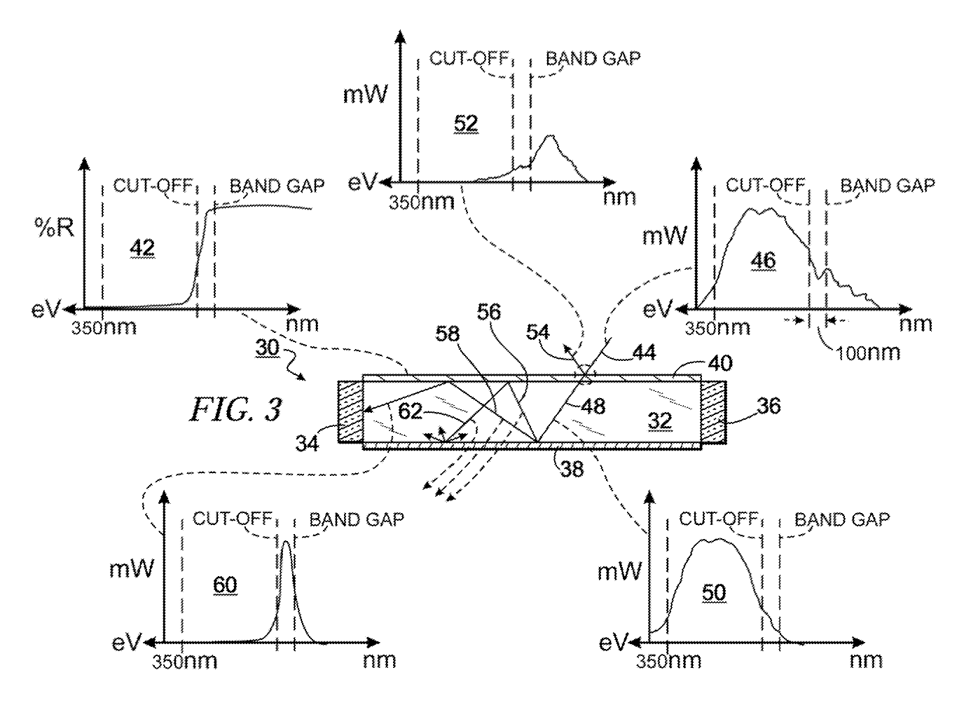

FIG. 3 shows a photovoltaic conversion assembly 30 in accordance with the invention. Assembly 30 comprises an optical slab 32, PV cells 32 and 34 mounted to edges of the optical slab 32, a down-converting means 38, and a two-way spectrally selective reflector 40. Reflectance graph 42 shows the reflectance properties of two-way reflector 40 in terms of percentage reflectance (vertical coordinate) versus photon energy (eV) and wavelength (nm) of light (horizontal coordinates). It will be noted that all graphs shown in FIG. 3 have the same horizontal coordinates, and that increasing photon energy is from right to left, whereas increasing wavelength of light is from left to right.

As can be seen in reflectance graph 42, a high level of reflectance occurs for wavelengths of light from a cut-off point and higher in a transmitted energy range. The “reflected energy range”—as used herein—preferably includes the highest band gap of PV cells 34 and 35, which is designated as just “BAND GAP” in all graphs in FIG. 3. Reference to a “highest” band gap is appropriate to account for multi-band gap PV cells; for a single band gap cell, “highest” band gap simply refers to the single band gap. The “transmitted energy range”—as used herein—extends from the cut-off point—defined as 50 percent reflectance on average for incident light at 90 degrees—to lower-wavelength (and higher energy) light preferably including 350 nm, which has been typically considered the lower-wavelength (higher energy) limit for practical conversion of light to electricity. However, US 2007/029583 A1 at ¶ [0033] suggests that even 280 nm light might be practically converted in the presence of down-converting means.

Incoming photons to be collected, which impinge on the upper major surface of optical slab 32, are exemplarily shown as incoming light 44. Incoming-light graph 46 shows a typical spectrum of solar or other light that is intended to be received by photovoltaic conversion assembly 30. Graph 46 and the remaining graphs in FIG. 3 to be described compare photon power in milliWatts (mW) (vertical coordinate) against photon energy and light wavelength; that is, the same horizontal coordinates as in reflectance graph 42. Of note in incoming-light graph 46 is that the bulk of incoming light energy is significantly above the band gap energy. As is known, photons with energy above the band gap of a PV cell will likely be absorbed by the PV cell and contribute to conversion to electrical energy, whereas photons with energy below the band gap will likely pass through the PV cell. It should be kept in mind, though, that the incoming light 44 still has yet to undergo interaction with down-converting layer 38, which will result in layer 38 absorbing such incoming light and emitting photons of lower energy. It is partly for this reason that the cut-off point in reflectance graph 42, incoming-light graph 46 and the other graphs in FIG. 3 is at a higher energy—or lower wavelength preferably by about 100 nm—than photons at the band gap energy level. In other words, in the first-described reflectance graph 42, the reflected energy range includes photons preferably about 100 nm lower in wavelength than the wavelength of photons having an energy equivalent to the band gap.

Transmitted light 48, which passes through two-way spectrally selective reflector 40, has a resulting transmitted-light graph 50, in which the light above the cut-off point (e.g., as shown in incoming-light graph 46) is cut off or heavily reduced. Conversely, as shown in reflected-light graph 52, light 54 that is reflected upwardly from the top surface of two-way reflector 40 is mostly above the cut-off point.

After transmitted light 48 within the optical slab reaches down-converting means 38, the photons of such light are absorbed by means 38 and, in turn, light in the form of photons 56 and 58, for example, are emitted at a lower energy level. Emitted-light graph 60 illustrates a preferred down-conversion of light energy, which can be seen generally as a shift of the illustrated curve to the right with respect to the curve in transmitted-light graph 50 together with a concentration of the curve between the cut-off point and the band gap. The light emitted from down-converting means 38 is preferably still mostly above the band gap, so that it can be absorbed by PV cells 34 or 36 and contribute to energy conversion. Meanwhile, it is desirable for the down-converting means 38 to emit photons that are lower in energy than the cut-off in emitted light graph 60. This is because it is likely that emitted photons from means 38 will strike the upper surface of the optical slab 32, and if they are higher in energy than the cut-off point of two-way spectrally selective reflector for upwardly directed light in FIG. 3, they will be transmitted upwardly through the two-way spectrally selective reflector 40 and be wasted.

Accordingly, it is desirable for the down-converting means to be chosen to produce, between the cut-off point and the band gap, the majority of its emitted light, more preferably more than 75 percent of its emitted light, and still more preferably more than 90 percent of its emitted light. The higher this percentage, the higher is the efficiency of light-to-electrical power conversion of the photovoltaic conversion assembly 40.

Beneficially, emitted light 56, which is at a high angle to the top of optical slab 32, does not exit the slab, due to the presence of two-sided spectrally selective reflector 40. The emitted light 56 is at a sufficiently lower energy (and higher wavelength) than the transmitted light 48 so as to be within the downwardly-directed reflected energy range of reflector 40. Thus, emitted light 56 becomes reflected back through the optical slab as reflected light 62, which may encounter down-converting means 38 where it is scattered without being absorbed by means 38 or is absorbed by means 38 with emission of a photon at the same or at a slightly lower energy level.

Without two-way spectrally selective reflector 40, emitted light 56 would have an angle, relative to the upper surface of the slab 32, too high to totally internally reflect within the optical slab and so would escape from the optical slab and be wasted as in the prior art of FIGS. 1 and 2.

Emitted light 58, in contrast to emitted light 56, is at a sufficiently low angle with respect to the upper surface of optical slab 32 that totally internally reflects at the upper surface of the optical slab so as to be redirected to PV cell 34.

Optical slab 32 may comprise a solid or hollow polymeric material, with high transparency (e.g., over 95 percent) in the “transmitted energy range” for two-way spectrally selective reflector 40, as defined above. Such material is preferably primarily composed of silicone or of a fluoropolymer or other polymer, any of which may be flexible at room temperature. PV cells 34 and 36 preferably comprise II-V on Si, epitaxial lift off material. Preferably, such cells are formed of a semi-conductor, such as Gallium-Arsenide, Silicon, Gallium Arsenide deposited on Silicon, Indium-Gallium-Phosphorus (InGaP) or Gallium-Tin (GaSb). The PV cells may be multi-junction II-VI or III-V cells, by way of example. The PV cells 34 and 36 may be adhered to the optical slab 32 with optical adhesive, or partially embedded in the slab, by way of example.

### (2) Definitions of Claim Terms

Whereas the top and bottom surfaces of optical slab 32 in FIG. 3 may be quadrangles, optical slab 32 may have different geometries than as shown in FIG. 3 or other figures. For instance, slab 32 could be shaped as a cylinder (not shown) or a prism (not shown), for instance. As used herein, the “first major surface” onto which light energy to be collected impinges, could occupy, for instance, 180 degrees around the perimeter of a cylinder; in such case, the “second major surface” as used herein, on which the down-converting means 38 is formed, could occupy less than 180 degrees around the perimeter of the cylinder. Between the first and second major surfaces is an “intermediate surface”—as used herein—which provides light to one or more PV cells. Or, the cylinder could be a foreshortened cylinder, with the foreshortened cylindrical surface being an “intermediate surface,” and the end surfaces of the cylinder being the first and second major surfaces. With a prism, having three surfaces arranged in triangular fashion, the first major surface could be the majority of a contiguous surface spanning two of the three triangularly arranged adjoining surfaces. The third triangularly arranged surface could then form the “second major surface,” as used herein, and the “intermediate surface” could be a surface between the first and second major surfaces.

Moreover, if the “first major surface” and “second major surface” of an optical slab are formed in respective planes, the planes do not need to be parallel to each other. If the planes are not parallel, the resulting thinnest edge may be suitable for placement of PV cells corresponding to PV cells 34 or 36 of FIG. 3. Where the first and second major surfaces are parallel to each other, the thickness of an optical slab is preferably no more than about 25 percent of a maximum orthogonal dimension of the slab. Assuming that the “first major surface” of an optical slab is, on average, directed upwardly, a desired concept is that the “first major surface,” which receives light energy from the sun, for instance, can be made several times larger than the vertical dimension of the slab. In other words, the “first major surface” available for receiving light from the sun, for instance, can be maximized in size in relation to the thickness of the slab. Somewhat different ways to state the foregoing relation are (1) the height of the optical slab (as viewed in FIG. 3, for instance) is within about plus or minus 25 percent of the any dimension of the “first major surface” of the optical slab, and (2) the height of the optical slab (as viewed in FIG. 3, for instance) is less than about 25 percent of any dimension of the “first major surface.”

Further, either or both of the “first major surface” and the “second major surface” of the optical slab can be curved, and these surfaces may meet along a line or at least come to within about 3 mm of each other. Further, the first major surface may not be a smooth surface, such as by incorporating a texture for enhanced optical performance.

Down-converting means 38 may comprise a phosphor-containing layer, quantum dots or dyes used to absorb light at one energy and emit light at a lower energy. Different types of such phosphor, quantum dots or dyes, etc., can be used together, and arranged homogeneously or in different concentrations on the surface of the optical slab. 32. Preferably, the different types of phosphors, etc., are arranged with the goal of maximizing conversion of incident light to the appropriate wavelength range, while minimizing re-absorption and re-emission as would result in lower photon energies. The appropriate wavelength range is described above in connection with FIG. 3. Further, combinations of phosphor, quantum dots and dyes can be used, such as phosphor-quantum dots, quantum dots and dyes, and dye-phosphor.

Two-way spectrally selective reflector 40 may be formed of a short-wave-pass dichroic filter (also known as a dichroic mirror), by way of example. Such a dichroic filter may be formed of alternating layers of materials such as those selected from silica, titania, tantala, zirconia, mag-flouride, or Zinc-Sulphide (ZnS). Such layers may be formed on glass that may be very thin, such as 10 mils (0.25 mm) or less. A preferred strain relief technique for such thin glass is described below. Two-way spectrally selective reflector 40 preferably covers at least the entire upper incoming-light receiving surface of photovoltaic conversion assembly 30, although the benefits of reflector 40 will be realized with lesser coverage. Another embodiment of reflector 40 will be described below.

Anti-reflective coatings (not shown) may be used on various surfaces of photovoltaic conversion assembly 30, to improve efficiency, as will be apparent to those of ordinary skill in the art.

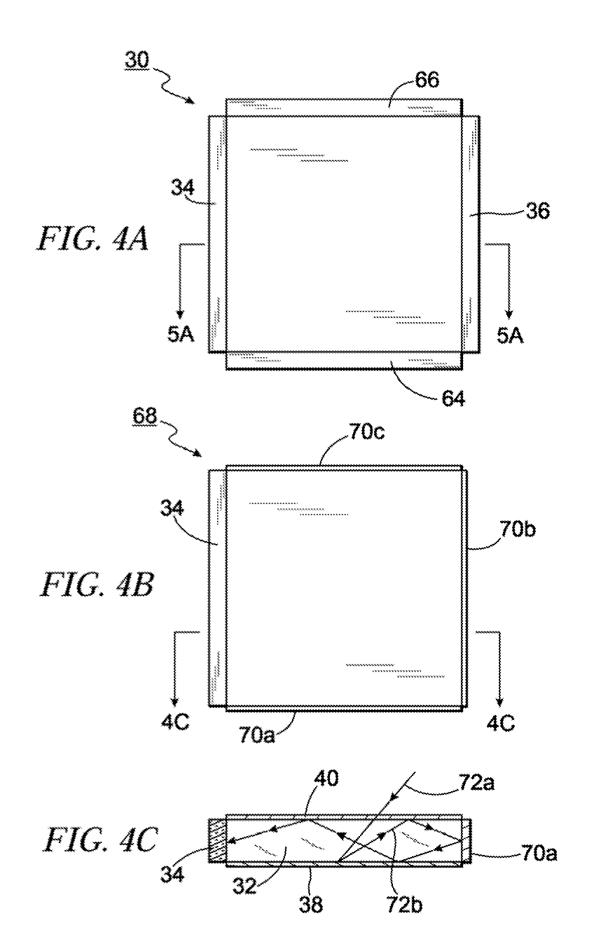

FIG. 4A shows an exemplary top view of photovoltaic conversion assembly 30 of FIG. 3. An exemplary arrangement of PV cells 34, 36, 64 and 66 is shown, each cell adjoining an edge of the assembly 30. Many other arrangements are possible, depending to a large extent on the following factors: (1) efficiency of PV cells used; (2) optical concentration desired (e.g., top surface of assembly 30 compared with inlet surfaces of PV cells); and (3) shaping of optical slab 32, presently shown in a simplified rectangular solid shape.

### (3) Other Embodiments

FIG. 4B shows a photovoltaic conversion assembly 68, wherein mirrors 70a, 70b and 70c replace PV cells 64, 36, and 66, respectively, on the edges of the optical slab 32 of photovoltaic conversion assembly 30 of FIG. 4A.

FIG. 4C shows operation of mirror 70a with regard to exemplary rays of light. Incoming light 72a passes through optical slab 32 and is absorbed by down-converting layer 38. In turn, layer 38 emits light 72b, which reflects from two-way spectrally selective reflector 40 to reach mirror 70a, from which it is reflected to down-converting means 38. If absorbed by down-converting means 38, means 38 will emit light that reaches PV cell 34 after reflection from two-way reflector 40; if light 72b is not absorbed by means 38, the light will be simply re-directed to reach PV cell after reflection from two-way reflector 40.

Mirrors 70a, 70b, and 70c of FIGS. 4B and 4C may be formed, by way of example, from any of at least one layer of metal, at least one layer of metal deposited onto a metal film, or MYLAR-brand polyester film on which a reflective metal layer is formed.

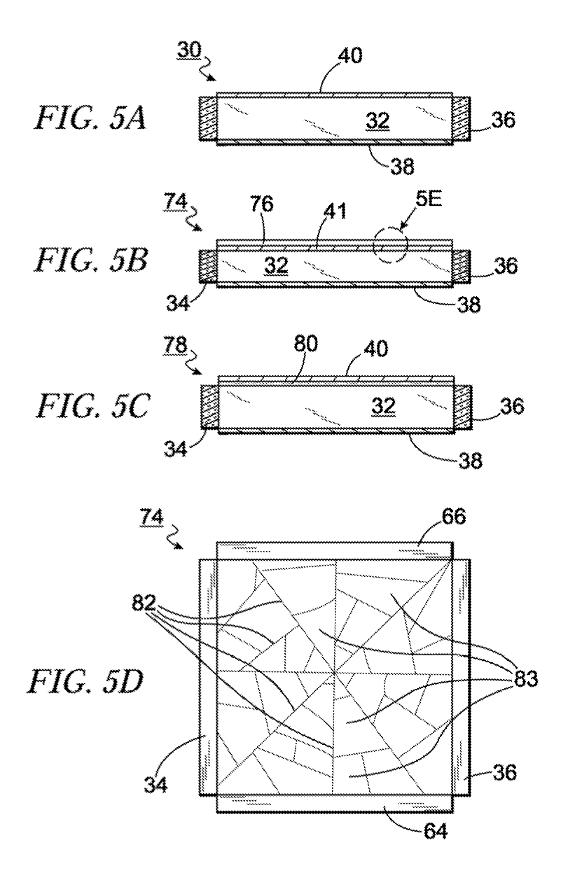

FIG. 5A shows photovoltaic conversion assembly 30, with two-way spectrally selective reflector 40 located above optical slab 32, as in FIG. 3. In contrast, FIG. 5B shows an alternatively configured assembly 74 wherein two-way spectrally selective reflector 41, which may be identical to reflector 40 of FIGS. 3 and 5A, is embedded in a flexible plastic layer 76. Flexible plastic layer 76 provides protection to reflector 41, especially where two-way reflector 41 is made of a dichroic filter.

FIG. 5C shows a photovoltaic conversion assembly 78, wherein there is provided a layer of adhesive that preferably has high transparency (e.g., over 95 percent) in the “transmissive energy range” as defined above in connection with two-way spectrally selective reflector 40 of FIG. 3.

FIG. 5D shows photovoltaic conversion assembly 74 of FIG. 5B from above. Of particular note are cracks or cuts 82 in a thin glass layer used to make two-way spectrally selective reflector 41, resulting in a plurality of separate pieces 83 of glass. Referring to FIG. 5E, the thin glass layer, mentioned above in connection with reflector 40 of FIG. 3, is used as a substrate 84 for the substrate dichroic filter 86. Substrate 84 and filter 86 form two-way reflector 41. By encapsulating the so-formed two-way reflector 41 in flexible plastic layer 76, and cracking the glass substrate 84 into a plurality of pieces 83, the so-formed two-way reflector 41 will be able to thermally expand at the same rate as the optical slab 32 that typically comprises a polymer. Alternatively, glass substrate 84 can be cut into a plurality of pieces 83 with any suitable means, as will be apparent to those of ordinary skill in the art. The pieces 83 are arranged with their edges adjacent to each other, rather than being stacked one atop the other.

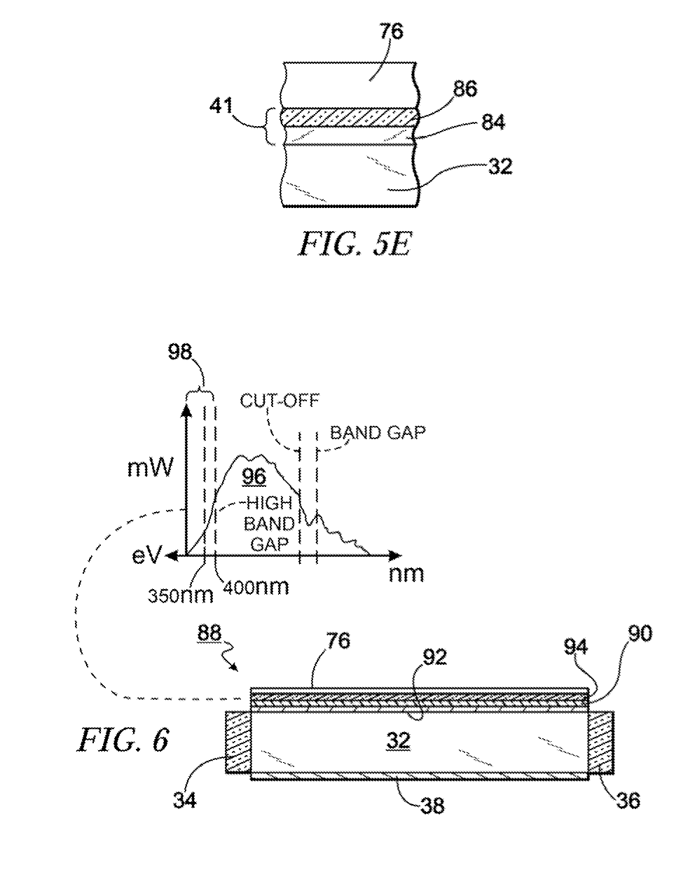

FIG. 6 shows a photovoltaic conversion assembly 88, generally similar to photovoltaic conversion assembly 74 of FIG. 5B, but including a high-band gap PV cell. By “high band gap” is meant a band gap substantially higher than the band gap of PV cells 34 and 36, which are mounted to receive light from edges of optical slab 32. Assembly 88 further includes a sapphire substrate layer 90 having on its lower surface a two-way spectrally selective reflector 92, such as described with other reference numbers above, and having on its upper surface a high band gap PV cell 94, such as a Gallium-Nitride (GaN) or Indium-Gallium-Nitride (InGaN) PV cell preferably with many layers. PV cell 94 may have a 400 nm band gap, by way of example.

Where PV cell 94 has a 400 nm band gap, as shown in graph 96—which is similar to graph 46 of FIG. 3 for incoming light—, photons with energy about 400 nm, as shown in graph 96, would be absorbed by cell to produce electricity. Higher wavelength photons, with lesser energy than the foregoing band gap, would simply pass through PV cell 94 and two-way reflector 92 in the same manner as described above, to cause photons to reach PV cells 34 or 36, etc. and be converted into electricity.

As shown in graph 96, energy range 98 above the high band gap of PV cell 94, preferably includes photons that would—except for PV cell 94—be absorbed in within optical slab 32 or by down-converting means 38, for example, and never reach lower band gap PV cells 34 or 36. In this way, PV cell 94 advantageously captures such photons that would otherwise never reach PV cells 34 and 36, for instance. In particular, among the photons absorbed by the high-band gap PV cell 94 and converted to electricity, it is preferred that at least 10 percent of the foregoing photons would otherwise never reach said at least one PV cell.

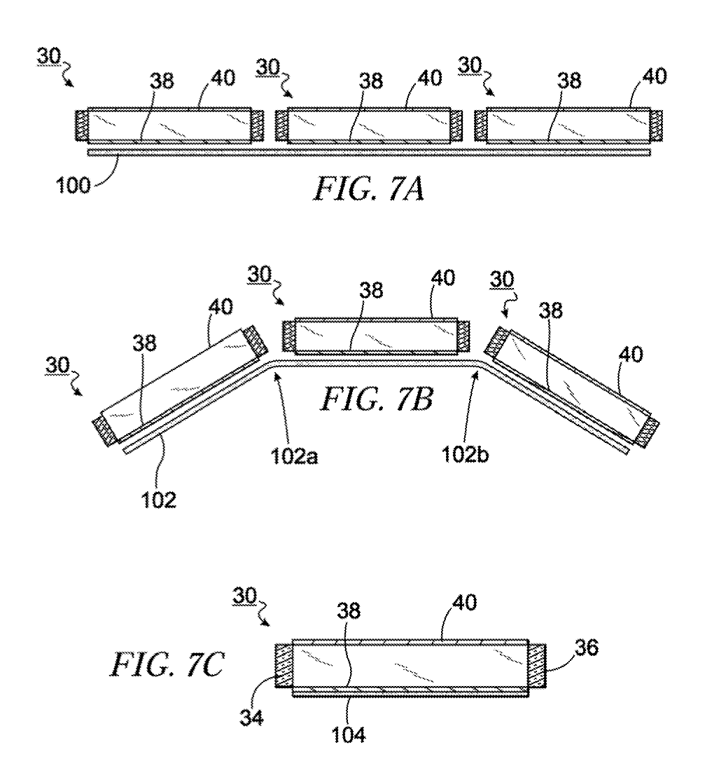

FIG. 7A shows three adjacent photovoltaic conversion assemblies 30, such as described in connection with FIG. 3 above. A common mirror 100 underlies and cooperates with the down-converting means 38 of each assembly 30. Common mirror 100 captures and reflects upwardly photons that are emitted by down-converting means 38 or pass through down-converting means 38. Such photons captured by common mirror 100 would otherwise be wasted.

By including common mirror 100, down-converting means 38 can be modified, as for example, by reducing phosphor, quantum dot or dye content if means 38 is formed from a phosphor-containing layer. A heavy concentration of phosphor, for instance, generates more opportunities for the photons to bounce off from, and thereby interact with, additional phosphor, providing more opportunity for photons to be reabsorbed and possibly lost in the system, not making it to the PV cells (e.g., 34 and 36, FIG. 3). Re-absorption of photons by the phosphor may lead to reduction in energy of photons to a point where the consequent emitted photons are below the band gap of the associated PV cells and cannot be absorbed by the PV cells. Common mirror 100 thus allows a lighter concentration of the down-converting means 38 to more efficiently contribute to the photovoltaic conversion process of the assemblies 30.

Common mirror 100 could be a high efficiency mirror, such as a sheet of MYLAR-brand polyester film with metal deposited onto its top surface (as viewed in FIG. 7A).

FIG. 7B is similar to FIG. 7A, but shows three adjacent photovoltaic conversion assemblies 30, with a common mirror 102 underlying the down-converting means 38 of each assembly. Common mirror 102 cooperates with each of the down-converting means 38 in the same way as mirror 100 of FIG. 7A, as just described.

Common mirror 102 of FIG. 7B is flexible, as indicated by bends 102a and 102b. It may be formed, by way of example, from a sheet of MYLAR-brand polyester film with metal deposited onto its top surface (as viewed in FIG. 7B).

Common mirrors 100 and 102 of FIGS. 7A and 7B can be positioned adjacent the respective down-converting means 38 of the associated photovoltaic conversion assemblies. They could also be adhered to the down-converting means with adhesive having a high transparency in the photon energy range of interest.

FIG. 7C shows a photovoltaic conversion assembly 30 in which an integrated mirror 104 underlies and cooperates with down-converting means 38 in the same way as described above with regard to mirror 102 of FIG. 7A. Mirror 102 could be a layer of metal or metal oxide deposited on the down-converting means 38. Alternatively, by way of example, mirror 104 could be a dichroic mirror made of alternating layers of thin film deposited material in the same general way as described above for implementing two-way spectrally selective reflector 40 of FIG. 3. However, the reflected energy range of mirror 104 would be tailored to reflect photons that reach the mirror—as described above in connection with FIG. 7A.

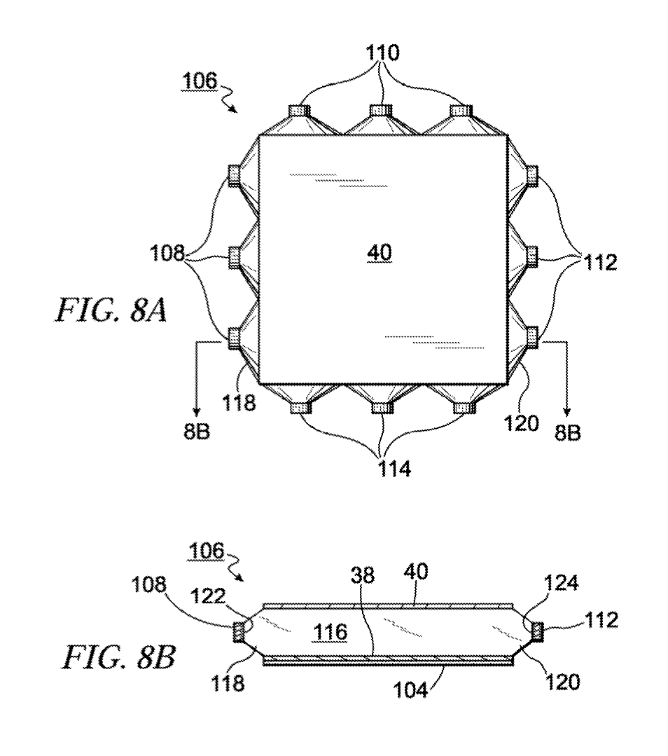

FIGS. 8A and 8B show a photovoltaic conversion assembly 106 in accordance with a preferred embodiment of the invention. Assembly 106 includes PV cells 108, 110, 112 and 114, which correspond, respectively, with reference to FIG. 5, to PV cells 34, 66, 36 and 64. Reference is made to the description of the foregoing PV cells in connection with FIG. 5 and to the description of cells 34 and 36 in connection with FIG. 3.

An optical slab 116, corresponding to optical slab 32 of FIG. 3, has tapered-down, sections, such as representative sections 118 and 120. Each of tapered-down sections 118 and 120 tapers down in cross section along a respective axis in convergence towards said axis to respective end-faces 122 and 124. By “convergence” is meant that the entire periphery of the cross section converges towards the respective axis. End-faces 122 and 124 transmit light to PV cells 108 and 112, respectively. The use of such tapered-down sections 118 and 120 achieves significant efficiency improvements compared to a photovoltaic conversion assembly 30 of FIG. 3, for instance, which lacks such sections.

Each of tapered-down sections 118 and 120 preferably is configured as a non-imaging concentrator of light. One of the useful attributes of a non-imaging concentrator is a so-called angle-to-area conversion of light, whereby high angle light at the inlet (unnumbered) areas of each section is “converted” to smaller angle light at the smaller end-faces of each section (e.g., 122 and 124). Smaller angle light at the end-faces, which is received by PV cells 108 and 112, may more easily pass into the PV cells and be converted to electricity.

Beneficially, photovoltaic conversion assembly 106 can achieve optical concentration that may include a 35× optical concentration. That is, the upper major surface of assembly 106 for receiving light energy to be collected can have 35 times the combined areas of the PV cells 108, 110, 112, and 114 that receive light energy from optical slab 116.

While the invention has been described with respect to specific embodiments by way of illustration, many modifications and changes will occur to those skilled in the art. It is, therefore, to be understood that the appended claims are intended to cover all such modifications and changes as fall within the true scope and spirit of the invention.

What is claimed is:

1. A photovoltaic conversion assembly, comprising:
a) an optical slab with first and second major surfaces and an intermediate surface therebetween; light energy to be collected impinging as incoming photons on the first major surface;
b) at least one PV cell mounted to receive light energy from the intermediate surface of the optical slab and convert said light energy to electrical energy; the PV cell having a highest band gap E;
c) a down-converting means located on the second major surface of the slab for converting to lower energy light received through the slab, with at least about 75 percent of the converted light having an energy level above the band gap E; and
d) a two-way spectrally selective reflector located proximate the first major surface for reflecting away from the slab incoming photons in a reflected energy range and transmitting into the slab higher energy incoming photons in an adjacent transmitted energy range; the reflected energy range extending from a cut-off point between the reflected and transmitted energy ranges and including the energy of the band gap E.

2. The invention of claim 1, wherein the down-converting means is chosen to produce, between the cut-off point and the band gap E, at least a predetermined percentage of said lower energy light; the percentage being 50.

3. The invention of claim 2, wherein the percentage is 75.

4. The invention of claim 3, wherein the percentage is 90.

5. The invention of claim 1, wherein the first and second major surfaces form quadrangles, and the intermediate surface comprises four edges.

6. The invention of claim 1, wherein the difference in value between the cut-off point and the band gap is approximately equivalent a wavelength difference between photons at the cut-off point and photons at the band gap E of 100 nm.

7. The invention of claim 1, wherein the down-converting means comprises one or more of at least one phosphor, at least one type of quantum dots, and at least one type of dye.

8. The invention of claim 1, wherein the transmitted energy range includes photons with wavelengths between 350 nm and the cut-off point.

9. The invention of claim 1, wherein at least some part or parts of the intermediate surface of the optical slab are respectively provided with a mirror for reflecting back into the slab light that reaches said mirror.

10. The invention of claim 1, wherein the two-way spectrally selective reflector comprises a plurality of pieces of glass substrate upon which a respective plurality of pieces of spectrally selective reflector is formed.

11. The invention of claim 1, further comprising a high-band gap PV cell located between the first major surface and the two-way spectrally selective reflector, with a band gap higher in energy than a said band gap E.

12. The invention of claim 11, wherein the band gap of the high-band gap PV cell is selected so that, among the photons absorbed by the high-band gap PV cell and converted to electricity, at least 10 percent of the foregoing photons would otherwise never reach said at least one PV cell.

13. The invention of claim 1, further comprising a mirror adjacent to the down-converting means for reflecting into the optical slab photons that reach said mirror.

14. The invention of claim 13, wherein the mirror is integrally joined to said assembly.

15. The invention of claim 1, wherein the optical slab includes on the intermediate surface a plurality of sections projecting away from the optical slab; each of said sections tapering down in cross section along a respective axis in convergence towards said axis to provide a tapered-down end-face for transmitting light to a respective PV cell.

16. The invention of claim 15, wherein the first and second major surfaces form quadrangles, and the intermediate surface comprises four edges.

17. The invention of claim 15, wherein the sections respectively comprise non-imaging concentrators of light.
